(19) United States
(12) Patent Application Publication
(10) Pub. No.: US 2025/0174960 A1
(43) Pub. Date: May 29, 2025

(54) LINE NARROWING LASER DEVICE, AND ELECTRONIC DEVICE MANUFACTURING METHOD

(71) Applicant: Gigaphoton Inc., Tochigi (JP)

(72) Inventor: Masakazu HATTORI, Oyama-shi (JP)

(73) Assignee: Gigaphoton Inc., Tochigi (JP)

(21) Appl. No.: 19/040,321

(22) Filed: Jan. 29, 2025

Related U.S. Application Data
(63) Continuation of application No. PCT/JP2022/033143, filed on Sep. 2, 2022.

(51) Int. Cl. H01S 3/137; H01S 3/08; H01S 3/13

(52) U.S. Cl. CPC H01S 3/137; H01S 3/08009; H01S 3/1305

(57) ABSTRACT

A line narrowing laser device includes a laser resonator including an output coupling mirror and a line narrowing module that includes a prism and a grating that has a reflection surface having a concave shape; a laser chamber including a pair of discharge electrodes, and arranged on an optical path of the laser resonator; a power source configured to apply, to the discharge electrodes, a high voltage pulse whose repetition frequency is variable; a wavefront adjuster including the output coupling mirror; a spectrum detector configured to measure a spectral line width of pulse laser light output from the output coupling mirror; and a processor configured to control the wavefront adjuster based on the measured spectral line width.

### CROSS-REFERENCE TO RELATED APPLICATIONS

The present application claims the benefit of International Application No. PCT/JP2022/033143, filed on Sep. 2, 2022, the entire contents of which are hereby incorporated by reference.

### BACKGROUND

### 1. Technical Field

The present disclosure relates to a line narrowing laser device and an electronic device manufacturing method.

### 2. Related Art

Recently, in a semiconductor exposure apparatus, improvement in resolution has been desired for miniaturization and high integration of semiconductor integrated circuits. For this purpose, an exposure light source that outputs light having a shorter wavelength has been developed. For example, as a gas laser device for exposure, a KrF excimer laser device for outputting laser light having a wavelength of about 248 nm and an ArF excimer laser device for outputting laser light having a wavelength of about 193 nm are used.

The KrF excimer laser device and the ArF excimer laser device each have a large spectral line width of about 350 to 400 pm in natural oscillation light. Therefore, when a projection lens is formed of a material that transmits ultraviolet rays such as KrF laser light and ArF laser light, there is a case in which chromatic aberration occurs. As a result, the resolution may decrease. Then, a spectral line width of laser light output from the gas laser device needs to be line-narrowed to the extent that the chromatic aberration can be ignored. For this purpose, there is a case in which a line narrowing module (LNM) including a line narrowing element (etalon, grating, and the like) is provided in a laser resonator of the gas laser device to line-narrow a spectral line width. A gas laser device with a narrowed spectral line width is referred to as a line narrowing gas laser device.

### LIST OF DOCUMENTS

### Patent Documents

Patent Document 1: US Patent Application Publication No. 2007/014326
Patent Document 2: U.S. Pat. No. 6,526,086

### SUMMARY

A line narrowing laser device according to an aspect of the present disclosure includes a laser resonator including an output coupling mirror and a line narrowing module that includes a prism and a grating that has a reflection surface having a concave shape; a laser chamber including a pair of discharge electrodes, and arranged on an optical path of the laser resonator; a power source configured to apply, to the discharge electrodes, a high voltage pulse whose repetition frequency is variable; a wavefront adjuster including the output coupling mirror; a spectrum detector configured to measure a spectral line width of pulse laser light output from the output coupling mirror; and a processor configured to control the wavefront adjuster based on the measured spectral line width.

An electronic device manufacturing method according to an aspect of the present disclosure includes generating pulse laser light using a line narrowing laser device, outputting the pulse laser light to an exposure apparatus, and exposing a photosensitive substrate to the pulse laser light in the exposure apparatus to manufacture an electronic device. Here, the line narrowing laser device includes a laser resonator including an output coupling mirror and a line narrowing module that includes a prism and a grating that has reflection surface having a concave shape; a laser chamber including a pair of discharge electrodes, and arranged on an optical path of the laser resonator; a power source configured to apply, to the discharge electrodes, a high voltage pulse whose repetition frequency is variable; a wavefront adjuster including the output coupling mirror; a spectrum detector configured to measure a spectral line width of the pulse laser light output from the output coupling mirror; and a processor configured to control the wavefront adjuster based on the measured spectral line width.

### BRIEF DESCRIPTION OF THE DRAWINGS

Embodiments of the present disclosure will be described below merely as examples with reference to the accompanying drawings.

FIG. 1 schematically shows the configuration of an exposure system according to a comparative example.

FIG. 2 schematically shows the configuration of a laser device according to the comparative example.

FIG. 3 is a graph showing an example of output timing of pulse laser light.

FIG. 4 is a flowchart showing a procedure of spectral line width control in the comparative example.

FIG. 5 shows an example of a spectrum waveform for explaining E95.

FIG. 6 shows a measurement result of a variation of the spectral line width in accordance with the repetition frequency of the pulse laser light in the comparative example.

FIG. 7 shows a simulation result of a variation of the spectral line width according to the repetition frequency of the pulse laser light in the comparative example.

FIG. 8 schematically shows the configuration of the laser device according to a first embodiment.

FIG. 9 shows the configuration of a line narrowing module according to the first embodiment.

FIG. 10 shows the configuration of a wavefront adjuster according to the first embodiment.

FIG. 11 is a graph showing simulation results of the spectral line width of the pulse laser light in accordance with a g parameter of a grating and the wavefront adjuster.

FIG. 12 shows a measurement result of a variation of the spectral line width in accordance with the repetition frequency of the pulse laser light in the first embodiment.

FIG. 13 shows a simulation result of a variation of the spectral line width in accordance with the repetition frequency of the pulse laser light in the first embodiment.

FIG. 14 is a graph showing a simulation result of the relationship between the g parameter and a pulse energy of the grating.

FIG. 15 schematically shows the configuration of the laser device according to a second embodiment.

FIG. 16 schematically shows the configuration of the laser device of a third embodiment.

FIG. 17 shows a power oscillator shown in FIG. 16 viewed from a direction different from that of FIG. 16.

### DESCRIPTION OF EMBODIMENTS

### Contents

1. Comparative example
1.1 Configuration of exposure apparatus 100
1.2 Operation of exposure apparatus 100
1.3 Configuration of laser device 1
   1.3.1 Laser resonator
   1.3.2 Monitor module 16
1.4 Operation of laser device 1
   1.4.1 Laser control processor 30
   1.4.2 Laser oscillation
   1.4. 3 Monitor module 16
   1.4.4 Burst oscillation
   1.4.5 Control of spectral line width
1.5 Problem of comparative example
   2. Laser device 1a including grating 14c having concave surface
2.1 Configuration
2.2 g parameter g_Grating of grating 14c
2.3 g parameter g_EFM of wavefront adjuster 15a
2.4 Relationship between g parameter and spectral line width
2.5 Relationship between g parameter and pulse energy
2.6 Effect
   3. Laser device 1b including master oscillator MO and power oscillator PO
3.1 Configuration
3.2 Operation
   3.2.1 Laser control processor 30
   3.2.2 Master oscillator MO
   3.2.3 Power oscillator PO
3.3 Effect
   4. Laser device 1c including ring resonator
4.1 Configuration
4.2 Operation
4.3 Effect

### 5. Others

Hereinafter, embodiments of the present disclosure will be described in detail with reference to the drawings. The embodiments described below show some examples of the present disclosure and do not limit the contents of the present disclosure. Also, all configurations and operation described in the embodiments are not necessarily essential as configurations and operation of the present disclosure. Here, the same components are denoted by the same reference numeral, and duplicate description thereof is omitted.

### 1. Comparative Example

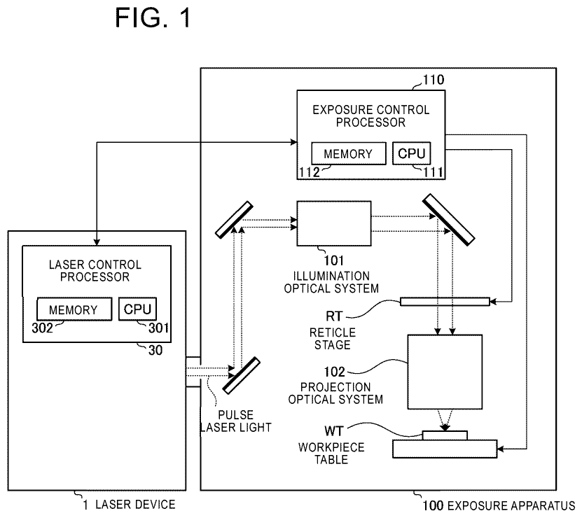

FIG. 1 schematically shows the configuration of an exposure system in a comparative example. The comparative example of the present disclosure is an example recognized by the applicant as known only by the applicant, and is not a publicly known example admitted by the applicant.

The exposure system includes a laser device 1 and an exposure apparatus 100. The laser device 1 includes a laser control processor 30. The laser control processor 30 is a processing device including a memory 302 in which a control program is stored, and a central processing unit (CPU) 301 which executes the control program. The laser control processor 30 is specifically configured or programmed to perform various processes included in the present disclosure. The laser control processor 30 corresponds to the processor in the present disclosure. The laser device 1 corresponds to the line narrowing laser device in the present disclosure, and is configured to output pulse laser light toward the exposure apparatus 100.

### 1.1 Configuration of Exposure Apparatus 100

The exposure apparatus 100 includes an illumination optical system 101, a projection optical system 102, and an exposure control processor 110.

The illumination optical system 101 illuminates a reticle pattern of a reticle (not shown) arranged on a reticle stage RT with the pulse laser light incident from the laser device 1.

The projection optical system 102 causes the pulse laser light transmitted through the reticle to be imaged as being reduced and projected on a workpiece (not shown) arranged on a workpiece table WT. The workpiece is a photosensitive substrate such as a semiconductor wafer on which a resist film is applied.

The exposure control processor 110 is a processing device including a memory 112 in which the control program is stored and a CPU 111 which executes the control program. The exposure control processor 110 is specifically configured or programmed to perform various processes included in the present disclosure. The exposure control processor 110 performs overall control of the exposure apparatus 100 and transmits and receives various data and various signals to and from the laser control processor 30.

### 1.2 Operation of Exposure Apparatus 100

The exposure control processor 110 transmits setting data of a target spectral line width and a target pulse energy, and a trigger signal to the laser control processor 30. The laser control processor 30 controls the laser device 1 in accordance with these data and signals.

The exposure control processor 110 synchronously translates the reticle stage RT and the workpiece table WT in opposite directions to each other. Thus, the workpiece is exposed to the pulse laser light reflecting the reticle pattern.

By such an exposure process, the reticle pattern is transferred onto the semiconductor wafer. Thereafter, an electronic device can be manufactured through a plurality of processes.

### 1.3 Configuration of Laser Device 1

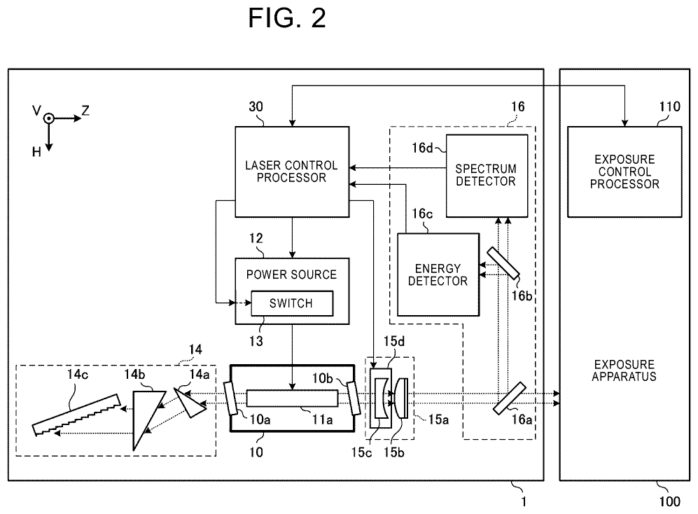

FIG. 2 schematically shows the configuration of the laser device 1 according to the comparative example. The laser device 1 includes a laser chamber 10, a discharge electrode 11a, a power source 12, a line narrowing module 14, a wavefront adjuster 15a, a monitor module 16, and the laser control processor 30. The laser device 1 is connectable to the exposure apparatus 100.

### 1.3.1 Laser Resonator

The wavefront adjuster 15a includes an output coupling mirror, and the output coupling mirror and the line narrowing module 14 configure a laser resonator. The laser chamber 10 is arranged on the optical path of the laser resonator. Windows 10a, 10b are arranged at both ends of the laser chamber 10. The discharge electrode 11a and a discharge electrode (not shown) paired with the discharge electrode 11a are arranged inside the laser chamber 10. The discharge electrode (not shown) is positioned so as to overlap with the discharge electrode 11a in the V-axis direction perpendicular to the paper surface. The V-axis direction corresponds to the first direction in the present disclosure. The laser chamber 10 is filled with a laser gas containing, for example, an argon gas or a krypton gas as a rare gas, a fluorine gas as a halogen gas, a neon gas as a buffer gas, and the like.

The power source 12 includes a switch 13 and is connected to the discharge electrode 11a and a charger (not shown).

The line narrowing module 14 includes a plurality of prisms 14a, 14b and a grating 14c. The prisms 14a, 14b are arranged in this order on the optical path of the light output from the window 10a. The surfaces of the prisms 14a, 14b on and from which the light is incident and output are both parallel to the V axis.

The grating 14c is arranged on the optical path of the light having transmitted through the prisms 14a, 14b. The direction of the grooves of the grating 14c is parallel to the V axis.

The wavefront adjuster 15a includes a cylindrical convex lens 15b and a cylindrical concave lens 15c.

The cylindrical convex lens 15b is a cylindrical plano-convex lens including a flat surface on which a partial reflection film is formed and a convex surface on the opposite side to the flat surface. The focal axis of the cylindrical convex lens 15b is parallel to the V axis.

The cylindrical concave lens 15c is a cylindrical plano-concave lens including a flat surface and a concave surface on the opposite side to the flat surface. The focal axis of the cylindrical concave lens 15c is parallel to the V axis. The cylindrical concave lens 15c is supported by a linear stage 15d. The linear stage 15d includes an actuator (not shown) that moves the cylindrical concave lens 15c along the optical path of the laser resonator, and a driver (not shown) that drives the actuator in accordance with a control signal from the laser control processor 30.

The convex surface of the cylindrical convex lens 15b and the concave surface of the cylindrical concave lens 15c face each other. The flat surface of the cylindrical convex lens 15b configures an output coupling mirror, and the convex surface of the cylindrical convex lens 15b and the cylindrical concave lens 15c configuring the wavefront adjuster 15a are located between the output coupling mirror and the laser chamber 10.

Although the flat surface of the cylindrical convex lens 15b configures the output coupling mirror, the cylindrical convex lens and the output coupling mirror may be configured by separate optical components. That is, the wavefront adjuster 15a may include, instead of the cylindrical convex lens 15b, an output coupling mirror configured by a planar substrate or a wedge substrate and having a partial reflection film, and a cylindrical convex lens located between the output coupling mirror and the laser chamber 10 without having a partial reflection film.

### 1.3.2 Monitor Module 16

The monitor module 16 is located on the optical path of the pulse laser light output from the output coupling mirror included in the wavefront adjuster 15a. The monitor module 16 includes beam splitters 16a, 16b, an energy detector 16c, and a spectrum detector 16d.

The beam splitter 16a is located on the optical path of the pulse laser light output from the output coupling mirror. The beam splitter 16a is configured to transmit a part of the pulse laser light toward the exposure apparatus 100 at high transmittance and to reflect other parts thereof. The beam splitter 16b is located on the optical path of the pulse laser light reflected by the beam splitter 16a. The energy detector 16c is located on the optical path of the pulse laser light reflected by the beam splitter 16b. The spectrum detector 16d is located on the optical path of the pulse laser light transmitted through the beam splitter 16b. The spectrum detector 16d includes an etalon (not shown) and a light distribution sensor (not shown).

### 1.4 Operation of Laser Device 1

### 1.4.1 Laser Control Processor 30

The laser control processor 30 transmits setting data of an application voltage to be applied to the discharge electrode 11a to the power source 12 based on the setting data of the target pulse energy received from the exposure control processor 110. The laser control processor 30 transmits a control signal to the linear stage 15d included in the wavefront adjuster 15a based on the setting data of the target spectral line width setting data received from the exposure control processor 110. Further, the laser control processor 30 transmits, to the switch 13 included in the power source 12, an oscillation trigger signal based on the trigger signal 1 received from the exposure control processor 110.

### 1.4.2 Laser Oscillation

The switch 13 is turned on when the oscillation trigger signal is received from the laser control processor 30. When the switch 13 is turned on, the power source 12 generates a high voltage pulse from the electric energy charged in a charger (not shown), and applies the high voltage pulse to the discharge electrode 11a.

When a high voltage pulse is applied to the discharge electrode 11a, discharge occurs inside the laser chamber 10. The laser medium in the laser chamber 10 is excited by the energy of the discharge and shifts to a high energy level. When the excited laser medium then shifts to a low energy level, light having a wavelength corresponding to the difference between the energy levels is emitted.

The light generated in the laser chamber 10 is output to the outside of the laser chamber 10 through the windows 10a, 10b. The beam width of the light output through the window 10a of the laser chamber 10 is expanded by the prisms 14a, 14b, and then the light is incident on the grating 14c.

The light incident on the grating 14c from the prisms 14a, 14b is reflected by a plurality of grooves of the grating 14c and is diffracted in a direction corresponding to the wavelength of the light.

The prisms 14a, 14b reduce the beam width of the diffracted light from the grating 14c and return the light to the laser chamber 10 through the window 10a.

The output coupling mirror included in the wavefront adjuster 15a transmits and outputs a part of the light output through the window 10b of the laser chamber 10, and reflects the other part back into the laser chamber 10 through the window 10b.

In this way, the light output from the laser chamber 10 reciprocates between the line narrowing module 14 and the output coupling mirror, and is amplified each time the light passes through the discharge space in the laser chamber 10. The light is line narrowed each time being turned back in the line narrowing module 14. Thus, the light having undergone laser oscillation and line narrowing is output as pulse laser light from the output coupling mirror. The repetition frequency of the pulse laser light is the same as the repetition frequency of the high voltage pulse applied to the discharge electrode 11a, and the repetition frequency changes in accordance with the repetition frequency of the trigger signal received from the exposure apparatus 100.

### 1.4.3 Monitor Module 16

The energy detector 16c detects the pulse energy of the pulse laser light and outputs the data of the pulse energy to the laser control processor 30. The data of the pulse energy is used by the laser control processor 30 to perform feedback control of the setting data of the application voltage to be applied to the discharge electrode 11a.

In the spectrum detector 16d, an interference fringe formed by the etalon (not shown) is measured by the light distribution sensor (not shown), and a fringe waveform indicating a light intensity distribution of the interference fringe is generated.

### 1.4.4 Burst Oscillation

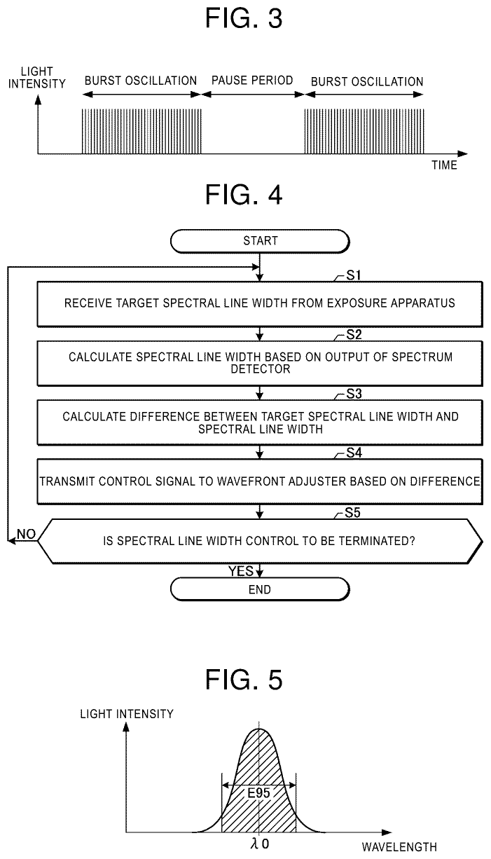

FIG. 3 is a graph showing an example of output timing of the pulse laser light. The laser device 1 performs laser oscillation at a repetition frequency equal to or higher than a predetermined value over a certain period in accordance with the trigger signal from the exposure control processor 110. Performing laser oscillation at a repetition frequency equal to higher than a predetermined value to output pulse laser light is referred to as “burst oscillation”.

When the trigger signal from the exposure control processor 110 is paused, the laser device 1 pauses the burst oscillation. Thereafter, in accordance with the trigger signal from the exposure control processor 110, the laser device 1 performs the burst oscillation again. A period between the first burst oscillation and the subsequent second burst oscillation is referred to as a “pause period”.

The period in which the burst oscillation is performed corresponds, for example, to the period in which exposure of one exposure area of a semiconductor wafer is performed in the exposure apparatus 100. The pause period corresponds, for example, to the period in which the imaging position of a reticle pattern is moved from one exposure area to another in the exposure apparatus 100 or the period in which the semiconductor wafer is replaced.

### 1.4.5 Control of Spectral Line Width

Referring back to FIG. 2, the linear stage 15d included in the wavefront adjuster 15a moves the cylindrical concave lens 15c along the optical path between the laser chamber 10 and the cylindrical convex lens 15b in accordance with a control signal output from the laser control processor 30. Thus, the wavefront of the light directed from the wavefront adjuster 15a toward the line narrowing module 14 changes. As the wavefront changes, the spectral line width of the pulse laser light changes.

FIG. 4 is a flowchart showing the procedure of spectral line width control in the comparative example. The processes shown in FIG. 4 are performed every time several to several tens of pulses of the pulse laser light are output.

In S1, the laser control processor 30 receives the target spectral line width from the exposure apparatus 100.

In S2, the laser control processor 30 calculates the spectral line width based on data of the fringe waveform output from the spectrum detector 16d.

Specifically, the laser control processor 30 extracts a part of the fringe waveform corresponding to the free spectral range of the etalon. The extracted part of the waveform shows the relationship between the distance from the center of concentric circles constituting the interference fringes and the light intensity. Next, the laser control processor 30 acquires a spectral waveform by performing coordinate conversion of the waveform into the relationship between the wavelength and the light intensity. The laser control processor 30 calculates the spectral line width based on the spectral waveform. The spectral line width may be the full width at half maximum or an index called E95.

FIG. 5 shows an example of a spectral waveform for explaining E95. In FIG. 5, the horizontal axis represents the wavelength and the vertical axis represents the light intensity. The total width of a portion occupying 95% of the total energy of the spectrum with a center wavelength λ0 as the center is represented by E95.

Referring back to FIG. 4, in S3, the laser control processor 30 calculates a difference ΔΔλ between the received target spectral line width and the calculated spectral line width.

In S4, the laser control processor 30 transmits a control signal to the wavefront adjuster 15a based on the difference ΔΔλ. Thus, feedback control is performed on the spectral line width of the pulse laser light.

In S5, the laser control processor 30 determines whether or not to terminate the control of the spectral line width. For example, in a case in which the burst oscillation for outputting the pulse laser light at a constant repetition frequency and the pause period starts, the control of the spectral line width is terminated. When the control of the spectral line width is to be terminated (S5: YES), the laser control processor 30 ends processing of the present flowchart. When the control of the spectral line width is not to be terminated (S5: NO), the laser control processor 30 returns processing to S1 and repeats the above-described operation.

### 1.5 Problem of Comparative Example

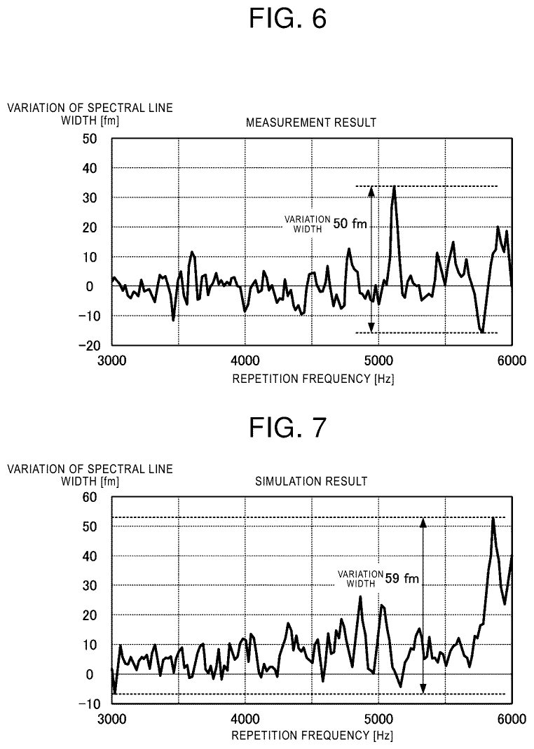

FIG. 6 shows a measurement result of a variation of the spectral line width in accordance with the repetition frequency of the pulse laser light in the comparative example. The variation of the spectral line width is measured by the following procedure. First, the first burst oscillation is performed with the repetition frequency of the pulse laser light being 6000 Hz, and the spectral line width is controlled using the wavefront adjuster 15a. Then, the control of the spectral line width using the wavefront adjuster 15a is paused, and the second burst oscillation subsequent to the first burst oscillation is performed with the repetition frequency of the pulse laser light being 4500 Hz, for example. The difference between the target spectral line width in the first burst oscillation and the average value of the spectral line widths of a predetermined number of pulses from the first pulse in the second burst oscillation is taken as the variation of the spectral line width. Similarly, after the first burst oscillation is performed with the repetition frequency being 6000 Hz, the variation of the spectral line width is measured with another switched repetition frequency.

FIG. 6 shows that the spectral line width varies 50 fm at maximum due to change in the repetition frequency of the pulse laser light. The maximum value of the spectral line width variation due to change of the repetition frequency is hereinafter referred to as the variation width.

FIG. 7 shows a simulation result of a variation of the spectral line width according to the repetition frequency of the pulse laser light in the comparative example.

FIG. 7 shows that the variation width of the spectral line width due to change of the repetition frequency of the pulse laser light is 59 fm.

When the pulse laser light is generated in the laser device 1, an acoustic wave is generated in the laser chamber 10. The acoustic wave is a compression wave of the gas, and when the acoustic wave reaches the optical path of the laser resonator in the laser chamber 10, a refractive index distribution is generated on the optical path due to a density distribution of the gas. Due to the refractive index distribution on the optical path, the wavefront of the light directed toward the line narrowing module 14 changes and the spectral line width of the pulse laser light changes. Since the relationship between the timing at which the acoustic wave reaches the optical path and the timing at which the light passes therethrough depends on the repetition frequency of the pulse laser light, it is considered that the spectral line width of the pulse laser light changes when the repetition frequency of the pulse laser light is changed.

Although feedback control is performed on the spectral line width using the wavefront adjuster 15a as described with reference to FIG. 4, the spectral line width may change significantly at the timing of switching the repetition frequency of the pulse laser light, and then it may take time for the spectral line width to converge to the target spectral line width by feedback control.

The repetition frequency of the pulse laser light is changed, for example, in the following cases:
(a) when the repetition frequency of the trigger signal received from the exposure control processor 110 is changed;
(b) when the repetition frequency is changed at the time of performing alignment of the laser device 1, and returned to the original repetition frequency after the alignment is completed; and
(c) when the repetition frequency is changed at the time of performing calibration of the laser device 1, and returned to the original repetition frequency after the calibration is completed.

Embodiments described below relate to suppressing a variation of the spectral line width when the repetition frequency of pulse laser light is changed.

### 2. Laser Device 1a Including Grating 14c Having Concave Surface

### 2.1 Configuration

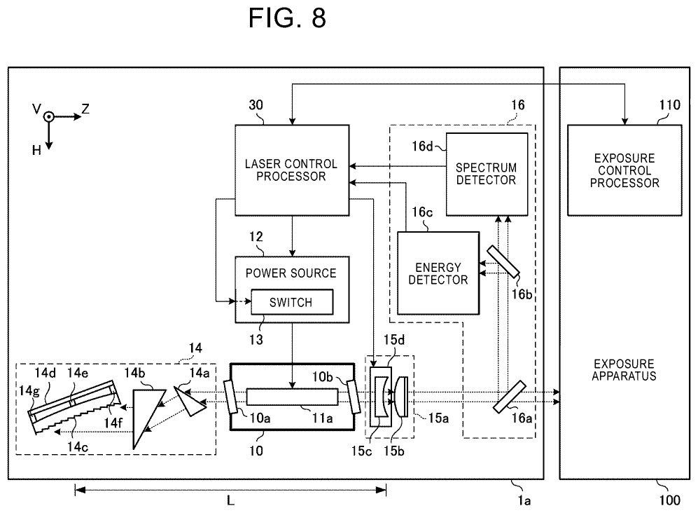

FIG. 8 schematically shows the configuration of the laser device 1a according to a first embodiment. The line narrowing module 14 included in the laser device 1a includes a grating 14c having a concave reflection surface. To adjust the shape of the reflection surface of the grating 14c, a grating bending mechanism including a holder 14d, an expansion portion 14e, and support portions 14f, 14g may be provided.

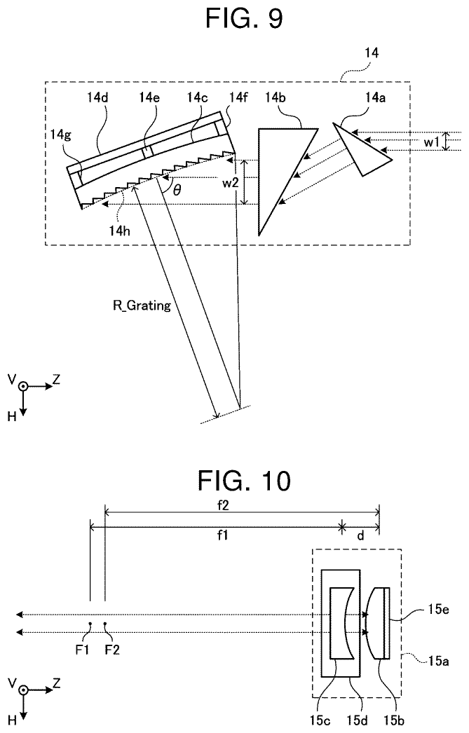

FIG. 9 shows the configuration of the line narrowing module 14 according to the first embodiment. The holder 14d included in the grating bending mechanism is located as facing the rear surface of the grating 14c, and the support portions 14f, 14g support both ends of the grating 14c. The expansion portion 14e located between the support portions 14f, 14g includes, for example, a bolt, and is configured to adjust the curvature of the reflection surface 14h of the grating 14c by adjusting the distance between the center part of the grating 14c and the holder 14d. When the distance is narrowed, the reflection surface 14h becomes concave, and when the distance is widened, the reflection surface 14h becomes convex.

The grating 14c includes a plurality of grooves and ridge lines parallel to the V axis, and the grooves and ridge lines are arranged in an alternating manner in a direction perpendicular to the V axis. A curved surface including these ridge lines, that is, a surface of the grating 14c that can be formed when all the grooves of the grating 14c are filled is defined as the reflection surface 14h of the grating 14c. The reflection surface 14h may be a part of a cylindrical shape curved in a plane perpendicular to the V axis, and the radius of the cylindrical shape is defined as a radius of curvature R_Grating. The radius of curvature R_Grating of the reflection surface 14h can be calculated from the measurement result obtained by measuring, by a wavefront measurement instrument (not shown), the wavefront of the light diffracted by the grating 14c and directed toward the prism 14b. As the wavefront measurement instrument, GPI-XP manufactured by Zygo Corporation (U.S.) can be used.

A beam magnification ratio M of the prisms 14a, 14b is given by the following expression, where the beam width in the direction perpendicular to the V axis of the light incident on the prism 14a from the laser chamber 10 is w1, and the beam width in the direction perpendicular to the V axis of the light incident on the grating 14c from the prism 14b is w2.

M=w2/w1

2.2 g Parameter g_Grating of Grating 14c

Let θ be the angle of incidence of the light incident on the grating 14c from the prism 14b. Let L be the optical path length between principal points of the grating 14c and the wavefront adjuster 15a (see FIG. 8). At this time, a g parameter g_Grating of the grating 14c is defined by the following expression.

g_Grating=1−(L×M²)/(R_Grating×cos θ)

When the reflection surface 14h is concave, the g parameter g_Grating is smaller than 1. For example, when the optical path length L between the principal points of the grating 14c and the wavefront adjuster 15a is 1×10³ mm, the beam magnification ratio M of the prisms 14a, 14b is 40 times, the reflection surface 14h is a concave surface having the radius of curvature R_Grating of 1×10⁷ mm, and the incident angle θ of the light incident on the grating 14c from the prism 14b is 70 degrees, the g parameter g_Grating is about 0.53.

When the reflection surface 14h is a convex surface, the g parameter g_Grating is larger than 1.

2.3 g Parameter g_EFM of Wavefront Adjuster 15a

FIG. 10 shows the configuration of the wavefront adjuster 15a according to the first embodiment. Here, the focal axis and the focal length of the cylindrical concave lens 15c are represented by F1 and f1, the focal axis and the focal length of the cylindrical convex lens 15b are represented by F2 and f2, and the distance between the principal points of the cylindrical concave lens 15c and the cylindrical convex lens 15b is represented by d. A g parameter g_EFM of the wavefront adjuster 15a is calculated as follows.

First, a combined focal length f_EFM of the wavefront adjuster 15a on the optical path entering the wavefront adjuster 15a from the laser chamber 10 and returning to the laser chamber 10 after being reflected by the partial reflection film 15e of the cylindrical convex lens 15b is calculated. A combined focal length f_EFM1 from the laser chamber 10 to the partial reflection film 15e is as follows.

f_EFM1=(f1×f2)/(f1+f2−d)

A combined focal length f_EFM2 from the partial reflection film 15e to the laser chamber 10 is the same as the combined focal length f_EFM1.

f_EFM2=f_EFM1

The combined focal length f_EFM of the wavefront adjuster 15a is as follows.

f_EFM=(f_EFM1×f_EFM1)/(f_EFM1+f_EFM1+δ1−δ2)

δ1 is the distance between the cylindrical concave lens 15c and the image-side principal point, and is calculated by the following expression.

δ1=f_EFM1×d/f2

δ2 is the distance between the cylindrical convex lens 15b and the object-side principal point, and is calculated by the following expression.

δ2=f_EFM1×d/f1

The g parameter g_EFM of the wavefront adjuster 15a is calculated as follows.

g_EFM=1−L/(2×f_EFM)

When the focal length f2 of the cylindrical convex lens 15b is smaller than the sum of the absolute value of the focal length f1 of the cylindrical concave lens 15c and the distance d between the principal points of the cylindrical concave lens 15c and the cylindrical convex lens 15b, the g parameter g_EFM is smaller than 1. For example, when the optical path length L between the principal points of the grating 14c and the wavefront adjuster 15a is 1×10³ mm, the focal length f1 is −70 mm, the focal length f2 is 74 mm, and the distance d is 6 mm, the g parameter g_EFM is about 0.58.

When the focal length f2 is larger than the sum of the absolute value of the focal length f1 and the distance d, the g-parameter g_EFM is larger than 1.

### 2.4 Relationship Between g Parameter and Spectral Line Width

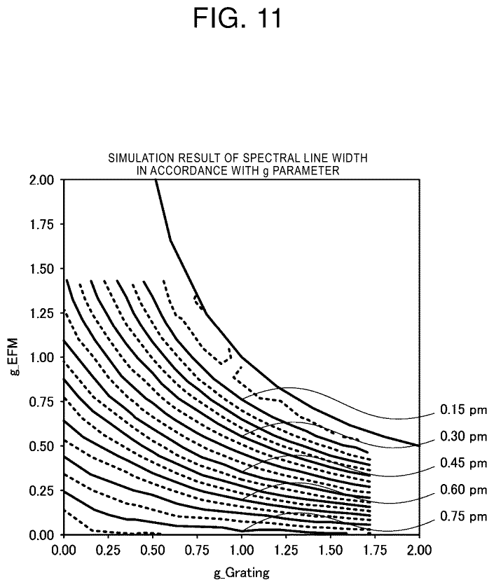

FIG. 11 is a graph showing simulation results of the spectral line width of the pulse laser light in accordance with the g parameter g_Grating of the grating 14c and the g parameter g_EFM of the wavefront adjuster 15a. In FIG. 11, the horizontal axis represents the g parameter g_Grating of the grating 14c, and the vertical axis represents the g parameter g_EFM of the wavefront adjuster 15a. The contour line of the spectral line width for each combination of the g-parameters is shown in the graph. The contour lines are drawn alternately by a solid line and a dotted line for each 0.0375 pm.

In the comparative example, since the reflection surface of the grating 14c is planar, the g parameter g_Grating of the grating 14c is 1. When the g parameter g_EFM of the wavefront adjuster 15a is changed with the g parameter g_Grating fixed to 1, the spectral line width of the pulse laser light is changed.

In the first embodiment, the reflection surface of the grating 14c has a concave shape, and the g parameter g_Grating of the grating 14c is smaller than 1. When the g parameter g_Grating is smaller than 1, the interval between the contour lines of the spectral line width becomes wider. That is, the spectral line width is more stable when the g parameter g_EFM of the wavefront adjuster 15a is changed. It is considered that the stability of the spectral line width when the refractive index distribution is generated on the optical path of the laser resonator by the acoustic wave is also increased.

In FIG. 11, the spectral line width of the pulse laser light may have a value from 0.15 pm to 0.75 pm, but the spectral line width is preferably equal to or larger than 0.15 pm and equal to or smaller than 0.5 pm.

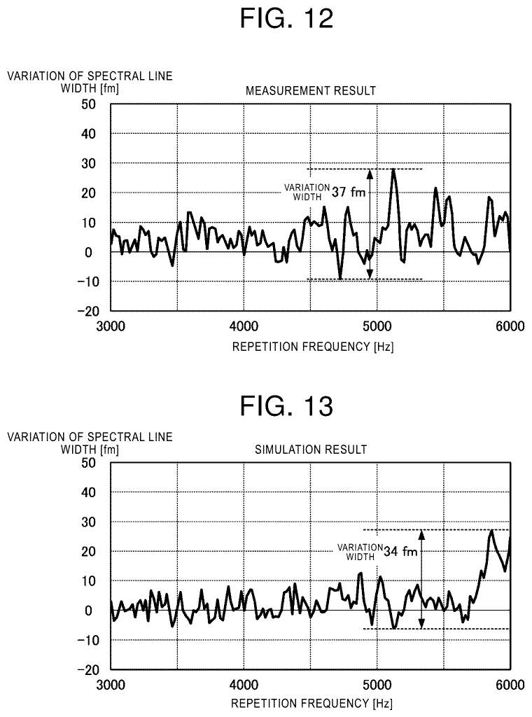

FIG. 12 shows measurement results of the variation of the spectral line width in accordance with the repetition frequency of the pulse laser light in the first embodiment. Here, the g parameter g_Grating of the grating 14c is set to 0.4.

FIG. 12 shows that the variation width of the spectral line width due to change in the repetition frequency of the pulse laser light is 37 fm.

FIG. 13 shows a simulation result of a variation of the spectral line width in accordance with the repetition frequency of the pulse laser light in the first embodiment. The g parameter g_Grating of the grating 14c is set to 0.4.

FIG. 13 shows that the variation width of the spectral line width due to change in the repetition frequency of the pulse laser light is 34 fm.

According to the first embodiment, the variation of the spectral line width when the repetition frequency of the pulse laser light is changed is suppressed, and the stability of the spectral line width is improved.

### 2.5 Relationship Between g Parameter and Pulse Energy

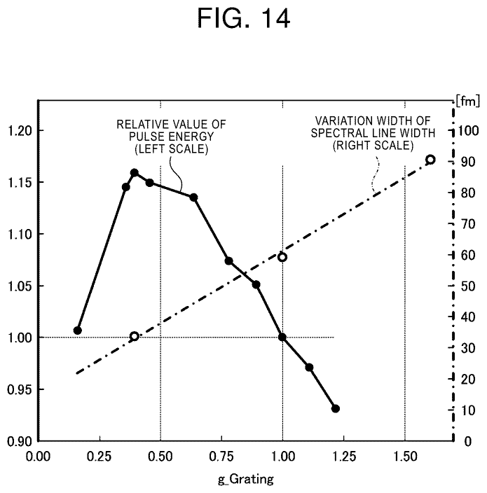

FIG. 14 is a graph showing a simulation result of the relationship between the g parameter g_Grating of the grating 14c and the pulse energy. The target spectral line width in simulating the pulse energy is set to 0.3 pm. FIG. 14 also shows the variation width of the spectral line width due to change in the repetition frequency of the pulse laser light. The horizontal axis of FIG. 14 indicates the g parameter g_Grating of the grating 14c, and the vertical axis indicates the relative value of the pulse energy with reference to the pulse energy when g_Grating is 1 or the variation width of the spectral line width.

Since the variation width of the spectral line width decreases as the g parameter g_Grating decreases, it is desirable that the g parameter g_Grating is small.

However, the pulse energy has a peak when the g parameter g_Grating is equal to or larger than 0.4 and smaller than 0.5, and the pulse energy becomes low even when the g parameter g_Grating is larger or smaller than the range. The pulse energy when the g parameter g_Grating is 0.2 is approximately the same as the pulse energy when the g parameter g_Grating is 1. When the g parameter g_Grating becomes smaller than 0.2 or equal to or larger than 1.0, the ratio of the light entering the wavefront adjuster 15a among the light diffracted by the grating 14c decreases, and it is considered that the pulse energy is decreased due to leakage to the outside of the laser resonator. Therefore, the g parameter g_Grating is preferably equal to or larger than 0.2 and smaller than 1.0, and more preferably equal to or larger than 0.4 and smaller than 0.5.

### 2.6 Effect

(1) According to the first embodiment, the laser device 1a includes the laser resonator, the laser chamber 10, the power source 12, the wavefront adjuster 15a, the spectrum detector 16d, and the laser control processor 30.

The laser resonator includes the output coupling mirror configured of the flat surface of the cylindrical convex lens 15b and the line narrowing module 14, the line narrowing module 14 includes the prisms 14a, 14b and the grating 14c, and the reflection surface 14h of the grating 14c has a concave shape.

The laser chamber 10 includes the discharge electrode 11a and the discharge electrode paired therewith, and is arranged on the optical path of the laser resonator.

The power source 12 is configured to apply a high voltage pulse to the discharge electrode 11a, and the repetition frequency of the high voltage pulse is variable.

The wavefront adjuster 15a includes the output coupling mirror.

The spectrum detector 16d generates a fringe waveform to measure the spectral line width of the pulse laser light output from the output coupling mirror and reflected by the beam splitter 16a.

The laser control processor 30 controls the wavefront adjuster 15a based on the measured spectral line width.

Accordingly, since the reflection surface 14h has a concave shape, the variation of the spectral line width due to change in the repetition frequency of the pulse laser light is suppressed, and the spectral line width is stabilized.

(2) According to the first embodiment, the value of g_Grating calculated by the expression g_Grating=1−(L×M²)/(R_Grating×cos θ) is equal to or larger than 0.2 and smaller than 1.0, where the radius of curvature of the reflection surface 14h of the grating 14c is R_Grating, the incident angle of the light incident on the grating 14c from the prisms 14a, 14b is 0, the optical path length from the principal point of the grating 14c to the principal point of the wavefront adjuster 15a is L, and the beam magnification ratio by the prisms 14a, 14b is M.

Accordingly, the spectral line width can be stabilized, and decrease in the pulse energy can be suppressed.

(3) According to the first embodiment, the value of g_Grating is equal to or larger than 0.4 and smaller than 0.5.

Accordingly, it is possible to stabilize the spectral line width and obtain high pulse energy.

(4) According to the first embodiment, the laser control processor 30 controls the wavefront adjuster 15a such that g_EFM calculated by the expression g_EFM=1−L/(2×f_EFM) is larger than the value of g_Grating, where the combined focal length of the wavefront adjuster 15a is f_EFM.

Accordingly, the target spectral line width can be realized by increasing the g parameter g_EFM of the wavefront adjuster 15a by the amount of decreasing the g parameter g_Grating of the grating 14c.

(5) According to the first embodiment, the laser control processor 30 is configured to control the wavefront adjuster 15a such that the spectral line width measured using the spectrum detector 16d is equal to or larger than 0.15 pm and equal to or smaller than 0.5 pm, and the g parameter g_Grating of the grating 14c is equal to or larger than 0.2 and smaller than 1.0.

Accordingly, the spectral line width is set to be equal to or larger than 0.15 pm and equal to or smaller than 0.5 pm, and the g parameter g_Grating of the grating 14c is set to be equal to or larger than 0.2 and smaller than 1.0, so that the spectral line width is stabilized and decrease in the pulse energy can be suppressed.

(6) According to the first embodiment, the grating 14c includes the plurality of grooves in the direction of the V axis, and the reflection surface 14h has a concave shape curved in a plane perpendicular to the V-axis direction.

Accordingly, the spectral line width can be stabilized by adjusting the wavefront shape in the plane perpendicular to the V-axis direction.

(7) According to the first embodiment, the surface of the prism 14a in and from which the light reciprocating in the laser resonator is incident and output and the surface of the prism 14b in and from which the light is incident and output are parallel to the V-axis direction.

Accordingly, by causing the light to be incident on the grating 14c while expanding the beam width in the plane perpendicular to the V-axis direction by the prisms 14a, 14b, the spectral line width can be narrowed.

(8) According to the first embodiment, the wavefront adjuster 15a includes the cylindrical convex lens 15b having the focal axis F2 parallel to the V-axis direction and the cylindrical concave lens 15c having the focal axis F1 parallel to the V-axis direction.

Accordingly, the spectral line width can be controlled by adjusting the wavefront shape in the plane perpendicular to the V-axis direction.

(9) According to the first embodiment, the wavefront adjuster 15a includes the cylindrical convex lens 15b, the cylindrical concave lens 15c, and the linear stage 15d. The cylindrical convex lens 15b includes the flat surface configuring the output coupling mirror and the convex surface located between the flat surface and the laser chamber 10. The cylindrical concave lens 15c is located on the optical path between the cylindrical convex lens 15b and the laser chamber 10. The linear stage 15d moves the cylindrical concave lens 15c.

Accordingly, since the cylindrical concave lens 15c is moved, the spectral line width can be controlled by adjusting the wavefront without changing the resonator length.

(10) According to the first embodiment, the line narrowing module 14 includes the grating bending mechanism including the holder 14d for adjusting the curvature of the grating 14c, the expansion portion 14e, and the support portions 14f, 14g.

Accordingly, the curvature of the reflection surface 14h of the grating 14c can be adjusted to an appropriate value.

In other respects, the first embodiment is similar to the comparative example.

### 3. Laser Device 1b Including Master Oscillator MO and Power Oscillator PO

### 3.1 Configuration

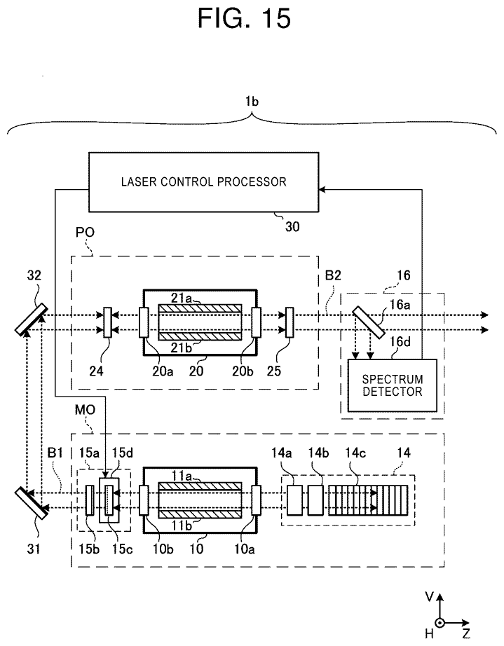

FIG. 15 schematically shows the configuration of a laser device 1b of a second embodiment. The laser device 1b includes the master oscillator MO, the power oscillator PO, the monitor module 16, the laser control processor 30, and high reflection mirrors 31, 32. The configuration of the laser control processor 30 is similar to the corresponding configuration in the first embodiment.

The master oscillator MO includes the laser chamber 10, the discharge electrode 11a, the line narrowing module 14, and the wavefront adjuster 15a. These configurations are similar to the corresponding configurations in the first embodiment, and the reflection surface of the grating 14c included in the line narrowing module 14 has a concave shape. FIG. 15 shows a discharge electrode 11b paired with the discharge electrode 11a. In FIG. 15, the power source 12 is not shown.

The high reflection mirrors 31, 32 are arranged on the optical path of pulse laser light B1 output from the master oscillator MO. Each of the high reflection mirrors 31, 32 is configured such that the position and posture thereof can be changed by an actuator (not shown). The high reflection mirrors 31, 32 configure a beam steering unit for adjusting an incident position and an incident direction of the pulse laser light B1 on the power oscillator PO.

The power oscillator PO is arranged on the optical path of the pulse laser light B1 that has passed through the beam steering unit. The power oscillator PO includes a laser chamber 20, a discharge electrode 21a and a discharge electrode 21b paired therewith, a rear mirror 24, and an output coupling mirror 25.

The rear mirror 24 is made of a material that transmits the pulse laser light B1, and one surface thereof is coated with a partial reflection film. The same applies to the output coupling mirror 25. Here, the reflectance of the rear mirror 24 is set higher than the reflectance of the output coupling mirror 25. The rear mirror 24 and the output coupling mirror 25 configure a laser resonator. The laser chamber 20 is arranged on the optical path of the laser resonator. Windows 20a, 20b are arranged at both ends of the laser chamber 20.

In other respects, the above-described components of the power oscillator PO are similar to the corresponding components of the master oscillator MO.

The monitor module 16 is arranged on the optical path of pulse laser light B2 output from the output coupling mirror 25. The configuration of the monitor module 16 is similar to the corresponding configuration in the first embodiment. In FIG. 15, the energy detector 16c and the beam splitter 16b are not shown.

### 3.2 Operation

### 3.2.1 Laser Control Processor 30

The laser control processor 30 receives setting data of a first target pulse energy of the pulse laser light B2 output from the power oscillator PO from the exposure control processor 110.

The laser control processor 30 further sets a second target pulse energy of the pulse laser light B1 output from the master oscillator MO.

The laser control processor 30 transmits the setting data of the application voltage to each of the power sources of the master oscillator MO and the power oscillator PO based on the first and second target pulse energies.

The laser control processor 30 transmits the first and second oscillation trigger signals based on the trigger signal received from the exposure control processor 110 to the switches included in the respective power sources of the master oscillator MO and the power oscillator PO.

### 3.2.2 Master Oscillator MO

The operation of the master oscillator MO is similar to the operation of the laser device 1a in the first embodiment.

### 3.2.3 Power Oscillator PO

When receiving the second oscillation trigger signal from the laser control processor 30, the power source included in the power oscillator PO generates a high voltage pulse and applies the high voltage pulse to the discharge electrode 21a.

The delay time of the second oscillation trigger signal to the power source included in the power oscillator PO with respect to the first oscillation trigger signal to the power source included in the master oscillator MO is set so that the timing at which discharge occurs in the laser chamber 20 is synchronized with the timing at which the pulse laser light B1 output from the master oscillator MO enters the laser chamber 20.

The pulse laser light B1 reciprocates between the rear mirror 24 and the output coupling mirror 25, and is amplified each time the pulse laser light B1 passes through the discharge space in the laser chamber 20. The amplified pulse laser light B2 is output from the output coupling mirror 25.

### 3.3 Effect

According to the second embodiment, by amplifying the pulse laser light B1 output from the master oscillator MO, it is possible to output the pulse laser light B2 having a higher pulse energy toward the exposure apparatus 100.

The spectral line width of the pulse laser light B2 depends on the spectral line width of the pulse laser light B1. By making the reflection surface of the grating 14c concave, the spectral line width of the pulse laser light B2 can be stabilized.

In other respects, the second embodiment is similar to the first embodiment.

### 4. Laser Device 1c Including Ring Resonator

### 4.1 Configuration

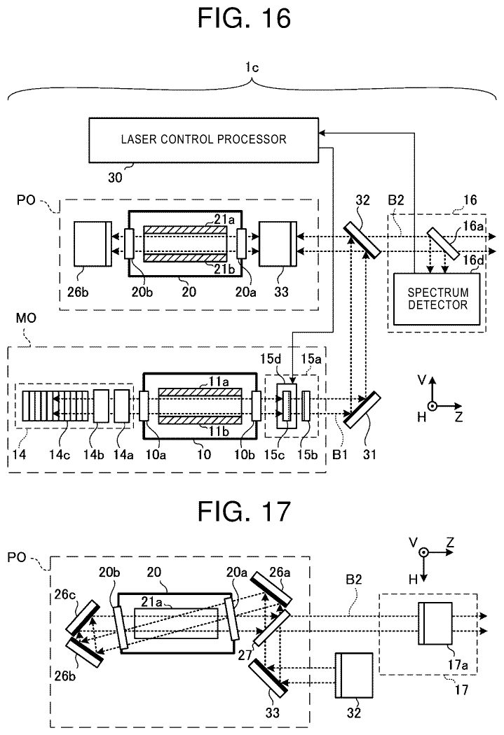

FIG. 16 schematically shows the configuration of a laser device 1c of a third embodiment. FIG. 17 shows the power oscillator PO shown in FIG. 16 as viewed from a direction different from that of FIG. 16. The laser device 1c includes the master oscillator MO, the power oscillator PO, the monitor module 16, the laser control processor 30, the and high reflection mirrors 31, 32. The configuration of the master oscillator MO is similar to the corresponding configuration in the second embodiment, and the reflection surface of the grating 14c included in the line narrowing module 14 has a concave shape.

The power oscillator PO includes the laser chamber 20, high reflection mirrors 26a to 26c, an output coupling mirror 27, and a high reflection mirror 33. The configuration of the laser chamber 20, the windows 20a, 20b provided therein, and the pair of discharge electrodes 21a, 21b are similar to the corresponding configuration in the second embodiment.

The output coupling mirror 27 and the high reflection mirror 26a are arranged outside the laser chamber 20 and in the vicinity of the window 20a. The high reflection mirrors 26b, 26c are arranged outside the laser chamber 20 and in the vicinity of the window 20b. At the discharge space inside the laser chamber 20, the optical path from the high reflection mirror 26a to the high reflection mirror 26b intersects with the optical path from the high reflection mirror 26c to the output coupling mirror 27. The laser resonator configured of the high reflection mirrors 26a to 26c and the output coupling mirror 27 is referred to as a ring resonator.

### 4.2 Operation

The pulse laser light B1 output from the master oscillator MO is reflected by the high reflection mirrors 31, 32, 33 in this order, and incident on the output coupling mirror 27 from the outside of the laser resonator of the power oscillator PO substantially in the −H direction. The pulse laser light B1 that enters the laser resonator through the output coupling mirror 27 is reflected by the high reflection mirrors 26a, 26b, 26c in this order, amplified when passing through the discharge space, and incident on the output coupling mirror 27 in the Z direction from the inside of the resonator.

A part of the pulse laser light B1 incident on the output coupling mirror 27 in the Z direction is reflected substantially in the −H direction, reflected again by the high reflection mirrors 26a, 26b, 26c, and amplified. Another part of the pulse laser light B1 incident on the output coupling mirror 27 in the Z direction is transmitted and output toward the exposure apparatus 100 as the pulse laser light B2.

### 4.3 Effect

According to the third embodiment, since return light from the power oscillator PO directed toward the master oscillator MO is unlikely to occur, the master oscillator MO can be stably operated.

In other respects, the third embodiment is similar to the second embodiment.

### 5. Others

The description above is intended to be illustrative and the present disclosure is not limited thereto. Therefore, it would be obvious to those skilled in the art that various modifications to the embodiments of the present disclosure would be possible without departing from the spirit and the scope of the appended claims. Further, it would be also obvious to those skilled in the art that the embodiments of the present disclosure would be appropriately combined.

The terms used throughout the present specification and the appended claims should be interpreted as non-limiting terms unless clearly described. For example, terms such as “comprise”, “include”, “have”, and “contain” should not be interpreted to be exclusive of other structural elements. Further, indefinite articles “a/an” described in the present specification and the appended claims should be interpreted to mean “at least one” or “one or more.” Further, “at least one of A, B, and C” should be interpreted to mean any of A, B, C, A+B, A+C, B+C, and A+B+C as well as to include combinations of any thereof and any other than A, B, and C.

What is claimed is:

1. A line narrowing laser device comprising:
a laser resonator including an output coupling mirror and a line narrowing module that includes a prism and a grating that has a reflection surface having a concave shape;
a laser chamber including a pair discharge electrodes, and arranged on an optical path of the laser resonator;
a power source configured to apply, to the discharge electrodes, a high voltage pulse whose repetition frequency is variable;
a wavefront adjuster including the output coupling mirror;
a spectrum detector configured to measure a spectral line width of pulse laser light output from the output coupling mirror; and
a processor configured to control the wavefront adjuster based on the measured spectral line width.

2. The line narrowing laser device according to claim 1,
wherein a value of g_Grating calculated by an expression g_Grating=1−(L×M²)/(R_Grating×cos θ) is equal to or larger than 0.2 and smaller than 1.0, where a radius of curvature of a reflection surface of the grating is R_Grating, an incident angle of light incident on the grating from the prism is θ, an optical path length from a principal point of the grating to a principal point of the wavefront adjuster is L, and a beam magnification ratio by the prism is M.

3. The line narrowing laser device according to claim 2,
wherein the value of g_Grating is equal to or larger than 0.4 and smaller than 0.5.

4. The line narrowing laser device according to claim 2,
wherein the processor controls the wavefront adjuster so that g_EFM calculated by an expression g_EFM=1−L/(2×f_EFM) becomes larger than the value of g_Grating, where a combined focal length of the wavefront adjuster is f_EFM.

5. The line narrowing laser device according to claim 2,
wherein the processor controls the wavefront adjuster so that the measured spectral line width becomes equal to or larger than 0.15 pm and equal to or smaller than 0.5 pm.

6. The line narrowing laser device according to claim 1,
wherein the grating includes a plurality of grooves in a first direction, and the reflection surface has a concave shape curved in a plane perpendicular to the first direction.

7. The line narrowing laser device according to claim 6,
wherein a surface of the prism on and from which light reciprocating in the laser resonator is incident and exits is parallel to the first direction.

8. The line narrowing laser device according to claim 6,
wherein the wavefront adjuster includes a cylindrical convex lens and a cylindrical concave lens each having a focal axis parallel to the first direction.

9. The line narrowing laser device according to claim 1,
wherein the wavefront adjuster includes a cylindrical plano-convex lens including a flat surface configuring the output coupling mirror and a convex surface located between the flat surface and the laser chamber, a cylindrical concave lens located on an optical path between the cylindrical plano-convex lens and the laser chamber, and an actuator configured to move the cylindrical concave lens.

10. The line narrowing laser device according to claim 1,
wherein the line narrowing module includes a grating bending mechanism configured to adjust a curvature of the grating.

11. An electronic device manufacturing method, comprising:
generating pulse laser light using a line narrowing laser device;
outputting the pulse laser light to an exposure apparatus; and
exposing a photosensitive substrate to the pulse laser light in the exposure apparatus to manufacture an electronic device,
the line narrowing laser device including:
a laser resonator including an output coupling mirror and a line narrowing module that includes a prism and a grating that has a reflection surface having a concave shape;
a laser chamber including a pair of discharge electrodes, and arranged on an optical path of the laser resonator;
a power source configured to apply, to the discharge electrodes, a high voltage pulse whose repetition frequency is variable;
a wavefront adjuster including the output coupling mirror;
a spectrum detector configured to measure a spectral line width of the pulse laser light output from the output coupling mirror; and
a processor configured to control the wavefront adjuster based on the measured spectral line width.

12. The electronic device manufacturing method according to claim 11,
wherein a value of g_Grating calculated by an expression g_Grating=1−(L×M²)/(R_Grating×cos θ) is equal to or larger than 0.2 and smaller than 1.0, where a radius of curvature of a reflection surface of the grating is R_Grating, an incident angle of light incident on the grating from the prism is θ, an optical path length from a principal point of the grating to a principal point of the wavefront adjuster is L, and a beam magnification ratio by the prism is M.

13. The electronic device manufacturing method according to claim 12,
wherein the value of g_Grating is equal to or larger than 0.4 and smaller than 0.5.

14. The electronic device manufacturing method according to claim 12,
wherein the processor controls the wavefront adjuster so that g_EFM calculated by an expression g_EFM=1−L/(2×f_EFM) becomes larger than the value of g_Grating, where a combined focal length of the wavefront adjuster is f_EFM.

15. The electronic device manufacturing method according to claim 12,
wherein the processor controls the wavefront adjuster so that the measured spectral line width becomes equal to or larger than 0.15 pm and equal to or smaller than 0.5 pm.

16. The electronic device manufacturing method according to claim 11,
wherein the grating includes a plurality of grooves in a first direction, and the reflection surface has a concave shape curved in a plane perpendicular to the first direction.

17. The electronic device manufacturing method according to claim 16,
wherein a surface of the prism on and from which light reciprocating in the laser resonator is incident and exits is parallel to the first direction.

18. The electronic device manufacturing method according to claim 16,
wherein the wavefront adjuster includes a cylindrical convex lens and a cylindrical concave lens each having a focal axis parallel to the first direction.

19. The electronic device manufacturing method according to claim 11,
wherein the wavefront adjuster includes a cylindrical plano-convex lens including a flat surface configuring the output coupling mirror and a convex surface located between the flat surface and the laser chamber, a cylindrical concave lens located on an optical path between the cylindrical plano-convex lens and the laser chamber, and an actuator configured to move the cylindrical concave lens.

20. The electronic device manufacturing method according to claim 11,
wherein the line narrowing module includes a grating bending mechanism configured to adjust a curvature of the grating.
